(19) United States
(12) Patent Application Publication
(10) Pub. No.: US 2002/0047754 A1
(43) Pub. Date: Apr. 25, 2002

(54) Traveling-wave amplifier having a II -type output transmission line structure

(76) Inventors: Jong In Song, Kwangju (KR); Jung Sun Lee, Kwangju (KR)

Correspondence Address: BACON & THOMAS, PLLC, 625 Slaters Lane - 4th Floor, Alexandria, VA, 22314-1176, US

(21) Appl. No.: 09/756,772

(22) Filed: Jan. 10, 2001

(30) Foreign Application Priority Data
Sep. 7, 2000 (KR) 10-2000-53218

(51) Int. Cl. H03F 3/60; H01P 5/12

(52) U.S. Cl. 333/125; 330/286

(57) ABSTRACT

The present invention relates to the traveling-wave amplifier having a π-type output transmission line structure.

In traveling-wave amplifiers having conventional output line structures including T-line and m-derived-line structures, additional capacitance and inductance are attached to the output of the transistors for velocity matching in input/output transmission lines in order to improve gain-bandwidth product. However, it is difficult to achieve velocity matching of output/input transmission lines without stability problem due to the influence of the additional capacitance and inductance through the feedback capacitance of the transistor used.

The present invention provides the traveling-wave amplifier having a π-type output transmission line structure, where the additional capacitance used for velocity matching of input/output transmission lines is connected in the middle of the output line. Since the additional element is isolated from the output of the transistor by the output transmission line, the π-type output transmission line structure can achieve velocity matching of output/input transmission lines without stability problem associated with the additional capacitance and the feedback capacitance of the transistor. The traveling-wave amplifier having a π-type output transmission line structure has an improved bandwidth, gain flatness, and stability compared to traveling-wave amplifiers having the conventional output line structures.

### BACKGROUND OF THE INVENTION

1. Field of the Invention

The present invention relates to a traveling-wave amplifier having a π-type output transmission line structure.

More particularly, it relates to the technique wherein improved bandwidth characteristics without degradation of stability of the traveling-wave amplifier can be gained by separating additional capacitances used for matching of the velocity of traveling-waves in the input and output transmission lines from the output of unit transistors.

2. Description of the Related Art

A traveling-wave amplifier is an ultra-wide-band amplifier and is widely used for microwave and millimeter-wave applications. It can be used as ultra-wide-band amplifiers in wireless communications and optical receivers in optical communications and microwave/millimeter wave-optical communications.

The bandwidth of ordinary amplifiers is typically limited to less than approximately 30% of the cutoff frequency(f_{T}) of the unit transistor used.

To improve the gain-bandwidth product of the ordinary amplifiers, the unit transistors can be simply connected in parallel to increase the gain of the amplifier.

In this case, however, the gain is increased, but the bandwidth is decreased. Thus, the expected gain-bandwidth product improvement cannot be achieved. The bandwidth of the ordinary amplifiers in which transistors are connected in parallel is decreased because capacitances (C_{g}, C_{d}, and C_{ds}) shown in the small signal equivalent circuit of FET are increased in proportion to the number of transistors that are simply connected in parallel.

The traveling-wave amplifier is used to overcome such limitation of the ordinary amplifiers in achieving improved gain-bandwidth product.

FIG. 1 shows a sub-section of the traveling-wave amplifier using Field Effect Transistors (FETs). This traveling-wave amplifier is not velocity-matched.

In FIG. 1, FET(1) and FET(2) are connected in parallel separated by drain lines, L_{d}(l) and L_{d}(2) and gate lines, L_{g}(l) and L_{g}(2).

If transistors are connected in the way shown in FIG. 1, the total gain of the amplifier is increased in proportion to the number of transistors.

Unlike the ordinary amplifiers where the unit transistors are simply connected in parallel, the capacitances(C_{g}, C_{d}, and C_{ds}) are separated by the transmission lines in the traveling-wave amplifier. Since these capacitances are separated by the transmission lines, the effective capacitances seen from the input and output of the unit transistors are not increased in proportion to the number of unit transistors. Therefore, the bandwidth of the individual unit transistors as well as the traveling-wave amplifier is not decreased. Thus, improved gain-bandwidth product of the traveling-wave amplifier can be obtained.

The improvement in the gain-bandwidth product of the traveling-wave amplifier can be maximized when the velocity of input traveling-wave signal propagating in the input transmission line(i.e. the gate line in case of traveling-wave amplifier using FETs) and the velocity of output traveling-wave signal propagating in the output transmission line(i.e. the drain line in case of traveling-wave amplifier using FETs) are matched.

In FIG. 1, a traveling-wave amplifier without velocity matching is illustrated. The input/output transmission lines(These are indicated as L_{g} and L_{d}) are simply connected to the input/output of unit transistors. In this structure, input/output impedances are determined by the following equations.

$$Zin = 50 Ω \approx \frac{\sqrt{Lg}}{\sqrt{Cin}} = \frac{\sqrt{Lg}}{\sqrt{Cg}} , \\ Zout = 50 Ω \approx \frac{\sqrt{Ld}}{\sqrt{Cout}} = \frac{\sqrt{Ld}}{\sqrt{Cd}} \qquad \text{[Equation 1]}$$

Also, the velocity of traveling-waves in the input(gate)/output(drain) transmission lines in this structure can be represented by the following equations.

$$Vin \approx \frac{1}{\sqrt{Cin \cdot Lg}} = \frac{1}{\sqrt{Cg \cdot Lg}} , \\ Vout \approx \frac{1}{\sqrt{Cout \cdot Ld}} = \frac{1}{\sqrt{Cd \cdot Ld}} \qquad \text{[Equation 2]}$$

To optimize the performance of traveling-wave amplifiers, input/output impedance should be matched to 50Ω and the velocity of traveling-waves in the input/output transmission lines should be matched. However, the above two matching conditions cannot be satisfied simultaneously for the structure of the traveling-wave amplifier shown in FIG. 1.

FIG. 2 is a small signal equivalent circuit of FET that is used for traveling-wave amplifiers. An example of small signal equivalent circuit parameter values of typical FET (gallium arsenide FET) is shown in Table 1.

TABLE 1

| Parameter | Value | Parameter | Value |
|---|---|---|---|
| C_{g} | 0.22 pF | Rᵢ | 3.09 Ω |
| C_{d} | 0.07 pF | R_{d} | 3.11 Ω |
| C_{gd} | 0.03 pF | gₘ | 27 mS |

As can be seen in Table 1, the input capacitance (C_{g}) of the transistor is generally larger than the output capacitance (C_{d}) of the transistor. Therefore, to meet the impedance matching condition, L_{g} value should be larger than L_{d} value.

With this condition, the velocity of traveling-wave signal (Vₒᵤₜ) in the output(drain) transmission line is larger compared to the velocity of traveling-wave signal (Vᵢₙ) in the input(gate) transmission line. This indicates that impedance and velocity matching conditions cannot be achieved and improvement in gain-bandwidth product of the simple traveling-wave amplifier structure shown in FIG. 1 is limited.

FIGS. 3 and 4 show conventional traveling-wave amplifier structures that can overcome the above limitation. FIG. 3 is a circuit diagram (a sub-section of multi-stage amplifier) of a traveling-wave amplifier having T-type drain line structure, and FIG. 4 is a circuit diagram (a sub-section of multi-stage amplifier) of a traveling-wave amplifier having m-derived type drain line structure.

FIG. 3 shows that the drain of FET(1) and additional capacitor C₂(1) are connected in parallel between drain lines and the gate terminal of said FET(1) is connected between gate lines.

FIG. 4 shows that the additional inductance L₂(1) is inserted between the drain terminal of the FET(1) and the output transmission lines.

In the said T-type drain line structure, to match the velocity of traveling-wave in the output line with the velocity of traveling-wave in the input line (i.e., to decrease the velocity of the traveling-wave in the output line), Cₒᵤₜ is increased by connecting an additional capacitance(C₂) to the output of the unit transistor. Equivalently, for the m-derived-line structure, an additional inductor is inserted in series between the drain of the transistor and the drain lines.

By increasing the output capacitance to Cₒᵤₜ=C_{d}+C₂ the Vₒᵤₜ value can be decreased to the value close to Vᵢₙ achieving the velocity matching of traveling-waves in the input/output transmission lines.

FIG. 5 shows the gain-frequency characteristics of 4-stage traveling-wave amplifiers with various drain line structures assuming that the value of the feedback capacitance C_{gd} of the unit transistor is 0 pF. As can be seen in the figure, bandwidth of the traveling-wave amplifiers having m-derived-type and T-type drain line structures are improved compared with the simple drain line structure (without any additional elements). The improvement is due to the velocity matching of traveling-waves in input/output transmission lines.

However, in general the feedback capacitance, C_{gd}, always exists in unit transistors, and thus the effect of additional elements associated with the feedback capacitance on amplifiers' characteristics has to be considered.

As the additional element values in the conventional drain line structures are increased to the values required for velocity matching, the stability of the amplifiers is degraded due to the presence of the feedback capacitance C_{gd}.

FIG. 6 shows the gain-frequency characteristics of traveling-wave amplifiers having different drain line structures when the feedback capacitance of the unit transistor C_{gd} is 0.03 pF.

Here, the additional element values attached in T-type or m-derived-type drain line structures are much smaller than the values needed for accurate velocity matching of input/output traveling-waves.

As shown in FIG. 6, while the bandwidth of traveling-wave amplifiers having T-type or m-derived drain line structures is increased very little compared to the traveling-wave amplifier having a simple drain line structure, gain peaking at the high frequency is already observed for T-type or m-derived drain line structures.

When the additional element values attached in T-type or m-derived-type drain line structures are increased to improve the bandwidth of the amplifiers, the gain peaking at the high frequency increases rapidly, degrading the stability of the amplifiers.

FIG. 7 shows the S11 of traveling-wave amplifiers having different drain line structures when the additional element values are close to the required values for velocity matching. As shown in FIG. 7, the S11 values of the traveling-wave amplifiers having T-type and m-derived type drain line structures are larger than 0 dB at the high-frequency region. The amplifiers show oscillatory behavior at the frequency where S11 value is larger than 0 dB.

In conclusion improvement of gain-bandwidth product of the two conventional traveling-wave amplifiers (having T-type drain line structure in FIG. 3 and m-derived drain line structure in FIG. 4) is limited due to the amplifier's stability problem associated with the additional elements directly connected to the output of unit transistors and the feedback capacitance C_{gd}.

### SUMMARY OF THE INVENTION

The presented invention relates to solve the said matter. The purpose of the present invention is overcoming the stability problem in conventional traveling-wave amplifier's due to the additional elements used for velocity matching associated with the feedback capacitance of unit transistors.

The technical theory to perform the said purpose of the presented invention is to provide a traveling-wave amplifier having a π-type transmission line structure, wherein the additional capacitance is attached in the middle of the drain transmission instead of being directly attached to the output of unit transistors.

In the π-type transmission line structure, since the additional capacitance is effectively isolate from the output of the unit transistor by the drain transmission line, the effect of the additional capacitance on amplifier's stability problem is reduced. Thus the traveling-wave amplifier having a π-type transmission line structure can achieve improved bandwidth, gain flatness, and stability compared to traveling-wave amplifiers having the conventional output transmission line structures.

### BRIEF DESCRIPTION OF DRAWINGS

FIG. 1 is a circuit diagram (a sub-section of a multi-stage amplifier) of a simple traveling-wave amplifier using FET, where no additional elements were used for velocity matching.

FIG. 2 is a diagram of the small signal equivalent circuit of unit FET used for traveling-wave amplifiers.

FIG. 3 is a circuit diagram (a sub-section of a multi-stage amplifier) of a traveling-wave amplifier having the conventional T-type drain line structure.

FIG. 4 is a circuit diagram (a sub-section of a multi-stage amplifier) of a traveling-wave amplifier having the conventional m-derived type drain line structure.

FIG. 5 is a graph showing the gain-frequency characteristics (when C_{gd}=0 pF) of a traveling-wave amplifiers having different drain line structures.

FIG. 6 is a graph showing the gain-frequency characteristics (when C_{gd}=0.03 pF) of a traveling-wave amplifiers having different drain line structures.

FIG. 7 is a graph showing the frequency characteristics of S11 (when C_{gd}=0.03 pF) for traveling-wave amplifiers having each of different drain line structures.

FIG. 8 is a circuit diagram (a sub-section of a multi-stage amplifier) of a traveling-wave amplifier having π-type drain line structure according to the present invention.

FIG. 9 is a circuit diagram showing the location of the additional capacitance in a traveling-wave amplifier having π-type drain line structure according to the present invention.

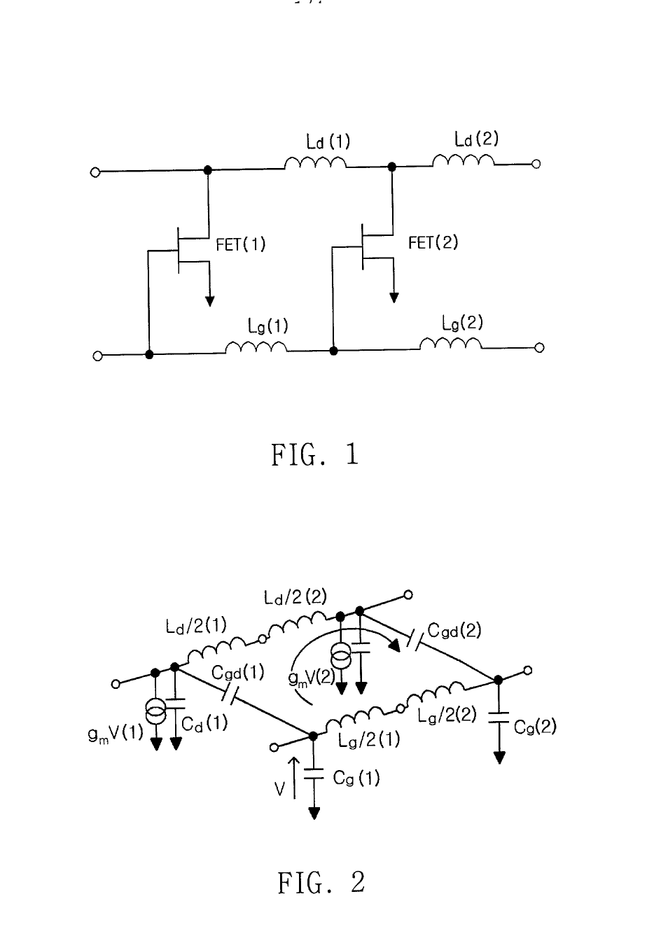

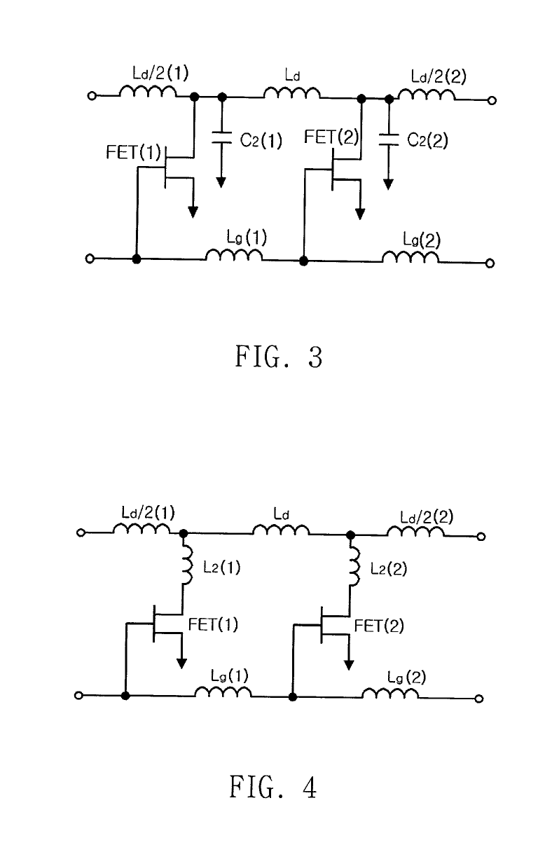

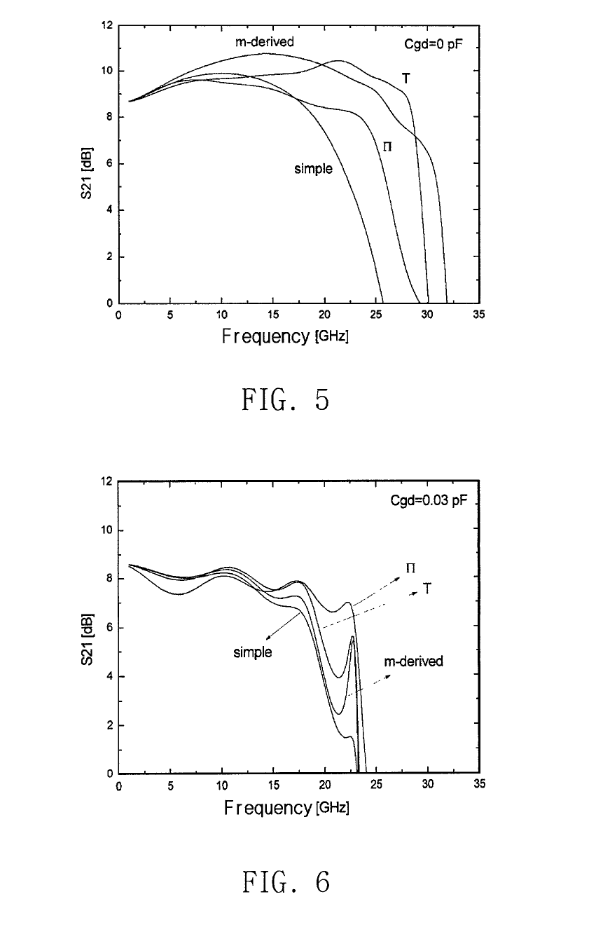

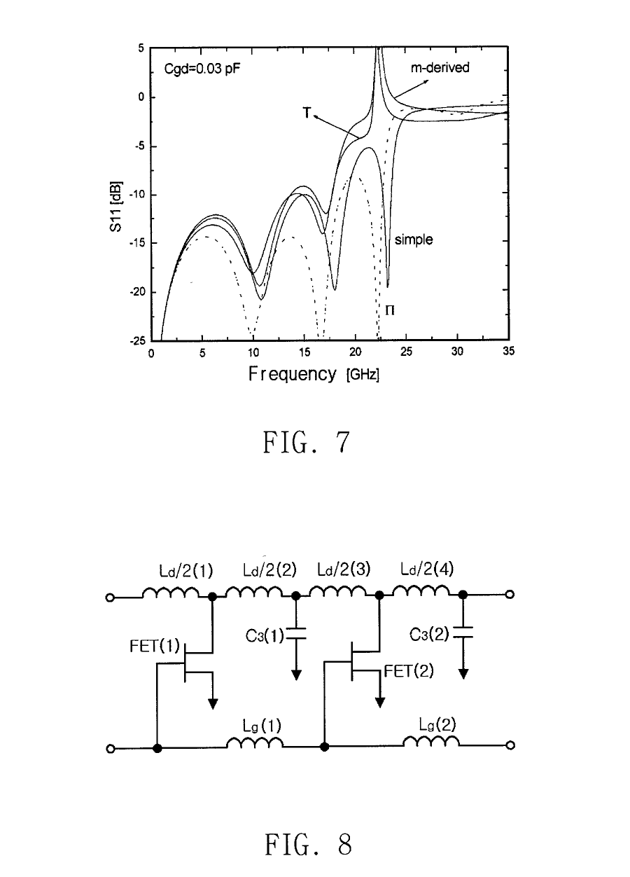

### DESCRIPTION OF THE EMBODIMENTS

The composition and operation of the present invention according to the preferred embodiment of the present invention will be explained with reference to the accompanying drawings.

FIG. 8 is a circuit diagram (a sub-section of a multi-stage amplifier) of a traveling-wave amplifier having π-type drain transmission line according to the present invention and FIG. 9 is a circuit diagram (a sub-section of a multi-stage amplifier) which shows the location of additional capacitance in the traveling-wave amplifier having π-type drain transmission line according to the present invention.

In FIG. 8, the drain terminal of FET(1) is connected between drain line L_{d}/2(1) and L_{d}/2(2), and the additional capacitance C₃(1) is connected between drain line L_{d}/2(2) and L_{d}/2(3).

Also, the drain terminal of FET(2) is connected between drain line L_{d}/2(3) and L_{d}/2(4), and the additional capacitance C₃(2) is connected to the drain line L_{d}/2(4).

Here, the gate terminal of the said FET(1) is connected to the gate line L_{g}(l), and the gate terminal of FET(2) is connected between L_{g}(l) and L_{g}(2).

The total length of drain line between the drain terminals of the said FET(1) and FET(2) is represented as L_{d}. The length of drain lines L_{d}/2(1)and L_{d}/2(3) is (1−x)L_{d} and that of L_{d}/2(2) and L_{d}/2(4) is x L_{d}.

While the additional capacitances or inductances for velocity matching of the conventional drain line structures are connected directly to the drain of unit transistors, the additional capacitance (C₃) in the π-type drain line structure is not directly connected to the output(drain) of unit transistors. Instead, it is isolated from the output(drain) of the unit transistor by drain transmission lines (e.g. L_{d}/2(1), L_{d}/2(2), L_{d}/2(3), and L_{d}/2(4)) as shown in FIG. 8.

In this structure, since the additional capacitance(C₃) is separated from the output(drain) of the unit transistor, the effective capacitance Cₒᵤₜ seen from the transistor's output(drain) is not increased much even if the C₃ value is increased large enough to achieve the velocity matching.

Therefore, the additional capacitance (C₃) value that is required to match the velocity of input/output traveling-waves perfectly can be used without stability problem.

The location of the additional capacitance can be anywhere in the drain line (i.e., 0<x<0 in FIG. 9). However, it is most effective in optimizing the gain-bandwidth product of traveling-wave amplifier having π-type drain transmission line structure when x value is 0.5.

In conclusion, the traveling-wave amplifier having π-type output transmission line structure according to the present invention can achieve the improved bandwidth characteristics without degradation of stability of amplifier by separating the additional capacitance used for matching the traveling-waves in the input/output transmission line from the output of the unit transistor.

The traveling-wave amplifier having π-type output transmission line structure according to the present invention allows an increased information processing capacity because it has an improved bandwidth and stability.

What is claimed is:

1. A traveling-wave amplifier having π-type output transmission line structure wherein in a periodic manner
(a)the drain terminal of FET(1) is connected between drain lines, L_{d}/2(1) and L_{d}/2(2),
(b)the additional capacitance C₃(1) is connected between drain lines L_{d}/2(2) and L_{d}/2(3),
(c)the gate terminal of the said FET(2) is connected between L_{g}(1) and L_{g}(2).

2. According to claim 1, the traveling-wave amplifier having π-type output transmission line structure wherein x value representing the location of the additional capacitance (C₃) is 0<x<1. If the length of the drain line between drain terminals of the said FET(1) and FET(2) is represented as L_{d}, the length of the said drain lines L_{d}/2(1) and L_{d}/2(3) is (1−x)L_{d} and that of the said drain lines L_{d}/2(2) and L_{d}/2(4) is x L_{d}.

3. According to claim 1, the traveling-wave amplifier having π-type output transmission line structure wherein the most effective bandwidth improvement can be gained when the x value is 0.5, where the additional capacitance C₃ is placed in the middle of the output transmission line (L_{d}).
